(19) United States
(12) Patent Application Publication
(10) Pub. No.: US 2017/0079136 A1
(43) Pub. Date: Mar. 16, 2017

(54) CIRCUIT BOARD AND METHOD FOR MAKING THE SAME

(71) Applicants: FuKui Precision Component (Shenzhen) Co., Ltd., Shenzhen (CN); HongQiSheng Precision Electronics (QinHuangDao) Co.,Ltd., Qinhuangdao (CN); Zhen Ding Technology Co., Ltd., Tayuan (TW)

(72) Inventors: SZU-HSIANG SU, New Taipei (TW); KUO-SHENG LIANG, New Taipei (TW); SHOU-JUI HSIANG, New Taipei (TW)

(21) Appl. No.: 14/920,634

(22) Filed: Oct. 22, 2015

(30) Foreign Application Priority Data
Sep. 16, 2015 (TW) 104130683

(51) Int. Cl. H05K 1/02; H05K 3/46; H05K 1/03

(52) U.S. Cl. CPC H05K 1/0298; H05K 1/03; H05K 3/4626

(57) ABSTRACT

A circuit board includes at least two substrates and an adhesive film sandwiched between the two substrates. Each substrate includes a base board. The base board includes conductive wires. Each base board is connected to the other base board by the adhesive film. The adhesive film includes two first adhesive layers and a second adhesive layer. The second adhesive layer is sandwiched between the two first adhesive layers. An adhesion force of the first adhesive layer is greater than an adhesion force of the second adhesive layer. A major composition of the second adhesive layer is rubber. The rubber is selected from a group consisting of isoprene rubber, styrene butadiene rubber, ethylene propylene rubber, butyl rubber, acrylic rubber, and polybutadiene rubber, and mixtures thereof.

### FIELD

The subject matter herein generally relates to a circuit board and a method for making the circuit board.

### BACKGROUND

A circuit board may include at least two substrates and an adhesive layer sandwiched between each two adjacent substrates. The adhesive layer may be made of acrylonitrile-butadiene rubber and epoxy resin. However, a signal attenuation generated in the adhesive film made of acrylonitrile-butadiene rubber and epoxy resin is great during the signal transmission. The adhesive layer made of other materials such as styrene butadiene rubber can reduce the signal attenuation, but an adhesion force of the adhesive layer is not enough to connect the substrates to cause structure of the circuit board to be firm.

### BRIEF DESCRIPTION OF THE DRAWINGS

Implementations of the present technology will now be described, by way of example only, with reference to the attached figures.

FIG. 1 is a diagrammatic cross-sectional view of an embodiment of a circuit board.

FIG. 2 is a diagrammatic cross-sectional view of an adhesive film used in the circuit board of FIG. 1.

FIG. 3 is a flowchart of an embodiment of a method for making a circuit board.

FIG. 4 is a diagrammatic cross-sectional view showing a first adhesive layer being connected to a release film.

FIG. 5 is a diagrammatic cross-sectional view showing a second adhesive layer being connected to the first adhesive layer of FIG.4.

FIG. 6 is a diagrammatic cross-sectional view showing another first second adhesive layer being connected to the second adhesive layer of FIG. 5 to form an adhesive film.

FIG. 7 is a diagrammatic cross-sectional view showing two substrates respectively formed on two opposite surfaces of the adhesive film of FIG. 6.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

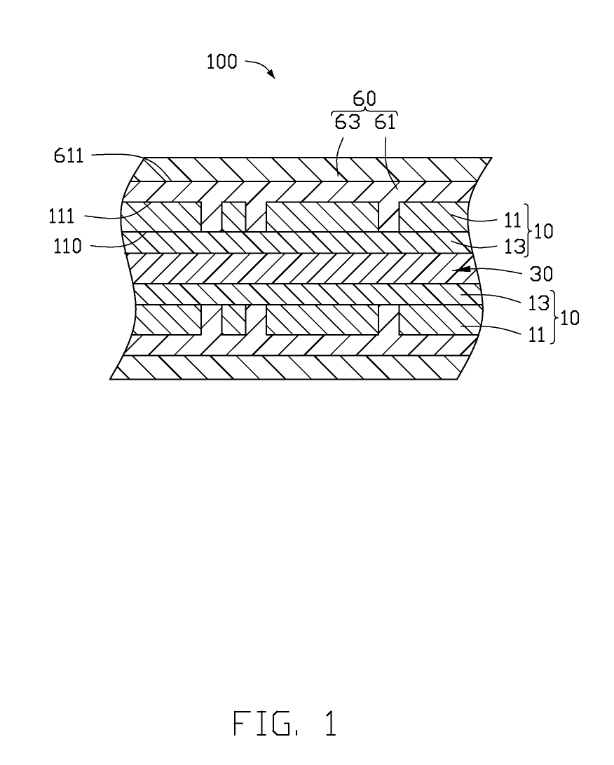

FIG. 1 illustrates an embodiment of a circuit board 100 employed in an electronic device (not shown). The electronic device can be a cell phone, a tablet computer, or a multimedia player. The circuit board 100 comprises at least two substrates 10 and an adhesive film 30 sandwiched between and adhering each two adjacent substrates 10. Each substrate 10 comprises a base board 11 and a dielectric layer 13 connected to a surface 110 of the base board 11. The dielectric layer 13 is sandwiched between the base board 11 and the corresponding adhesive film 30.

In one embodiment, the dielectric layer 13 is in direct contact with the corresponding adhesive film 30.

The base board 11 comprises conductive wires (not shown). The base board 11 can be a single-sided board or a double-sided board.

The dielectric layer 13 can be made of polyimide, liquid crystal polymer, or TEFLON.

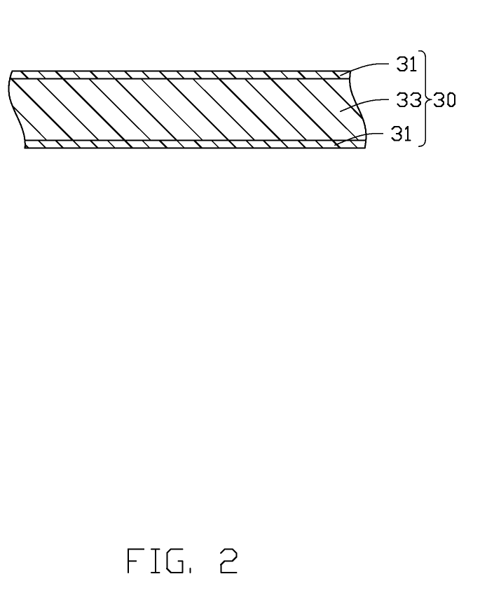

FIG. 2 illustrates that each adhesive film 30 comprises two first adhesive layers 31 and a second adhesive layer 33 sandwiched between the two first adhesive layers 31. The two first adhesive layers 31 of each adhesive film 30 are respectively connected to two dielectric layers 13 of the adjacent two substrates 10 (shown in FIG. 1). An adhesion force of the first adhesive layer 31 is greater than an adhesion force of the second adhesive layer 33. The first adhesive layer 31 comprises acrylonitrile-butadiene rubber and epoxy resin as a major composition. The second adhesive layer 33 comprises rubber as a major composition. The rubber is selected from a group consisting of isoprene rubber, styrene butadiene rubber, ethylene propylene rubber, butyl rubber, acrylic rubber, and polybutadiene rubber, and mixtures thereof. A ratio of a total thickness of the two first adhesive layers 31 with respect to a thickness of the adhesive film 30 is of about 0.1% to about 20%. Because a signal attenuation generated in each first adhesive layer 31 is greater than a signal attenuation generated in the adhesive film 33 when a signal is transmitted, thus, the thickness of the two first adhesive layers 31 can be reduced to decrease a total signal attenuation generated in the adhesive film 30, as long as the adhesive film 30 can adhere to the substrate 10. In at least one embodiment, the adhesive film 30 has a thickness of about 18 μm to about 40 μm. Each first adhesive layer 31 has a thickness of about 0.1 μm to about 3 μm. In at least one embodiment, the adhesive film 30 has a thickness of about 25 μm. Each first adhesive layer 31 has a thickness of about 1 μm.

The circuit board 100 further comprises two protective films 60 (shown in FIG. 1) respectively connected to surfaces 111 of the two outermost substrates 10 away from the adhesive film 30. Each protective film 60 comprises an insulating layer 61 and a protective layer 63. The insulating layer 61 is connected to the surface 111 of the base board 11 of the outmost substrate 10 away from the adhesive film 30. The protective layer 63 is connected to a surface 611 of the insulating layer 61 away from the base board 11.

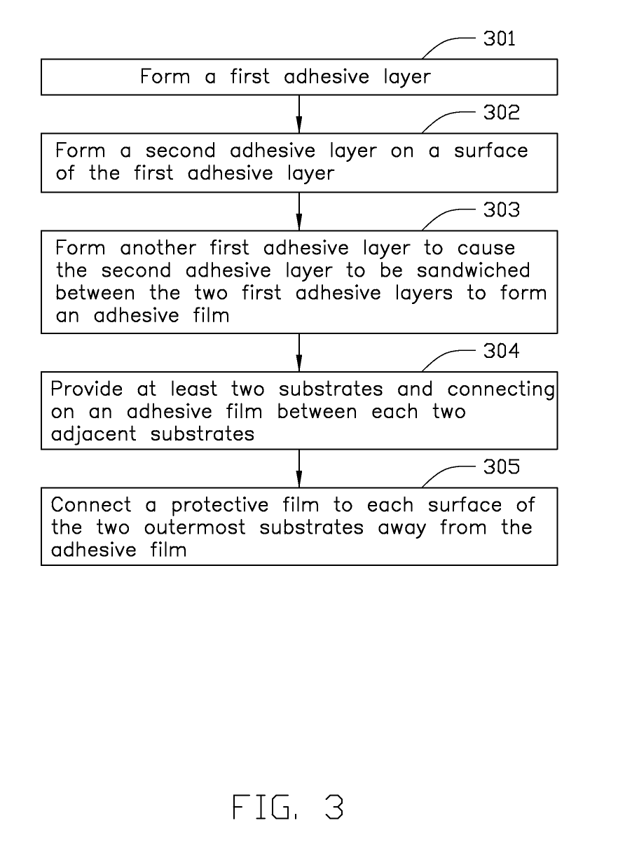

Referring to FIG. 3, a flowchart is presented in accordance with an exemplary embodiment. The exemplary method for making the circuit board 100 is provided by way of example, as there are a variety of ways to carry out the method. The method described below can be carried out using the configurations illustrated in FIGS. 1-2, for example, and various elements of these figures are referenced in explaining the example method. Each block shown in FIG. 3 represents one or more processes, methods or subroutines, carried out in the exemplary method. Furthermore, the illustrated order of blocks is by example only and the order of the blocks can change. Additional blocks may be added or fewer blocks may be utilized, without departing from this disclosure. The exemplary method can begin at block 300.

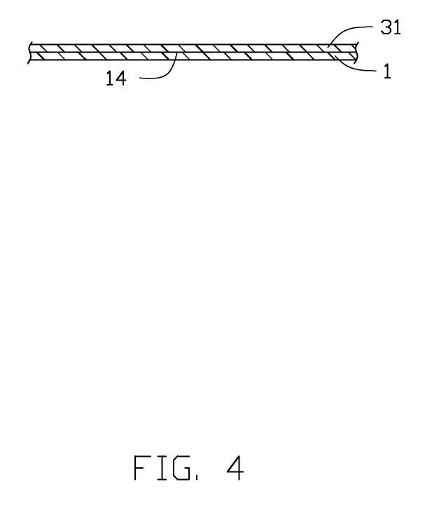

At block 301, FIG. 4 illustrates that a release film 1 is provided. A first adhesive layer 31 is formed on a surface 14 of the release film 1. The first adhesive layer 31 comprises acrylonitrile-butadiene rubber and epoxy resin as a major composition. In at least one embodiment, this may be carried out by dissolving the acrylonitrile-butadiene rubber and epoxy resin in butanone, and adding an additive to the butanone to form a first adhesive. The first adhesive is coated on the surface 14 of the release film 1, and is dried to form the first adhesive layer 31. The additive is selected from a group consisting of antiager, enhancer, and thickener, and mixtures thereof. The antiager can be made of N-isopropyl-N′-phenyl-4-phenylenediamin or poly(1,2-dihydro-2,2,4-trimethyl-quinoline).

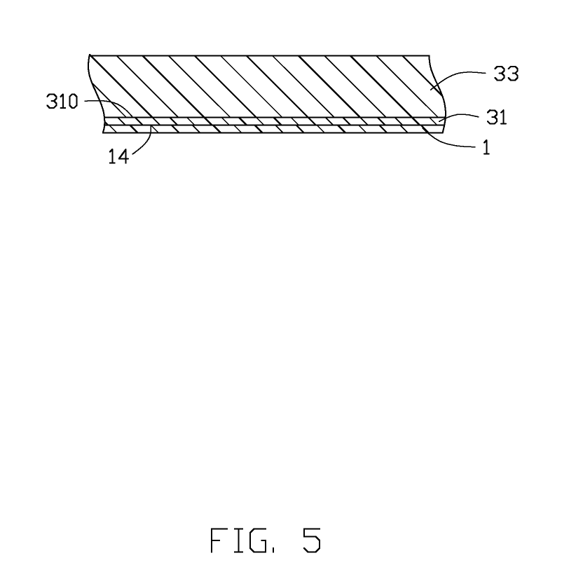

At block 302, FIG. 5 illustrates that a second adhesive layer 33 is formed on a surface 310 of the first adhesive layer 31 away from the release film 1. The second adhesive layer 33 comprises rubber as a major composition. The rubber is selected from a group consisting of isoprene rubber, styrene butadiene rubber, ethylene propylene rubber, butyl rubber, acrylic rubber, and polybutadiene rubber, and mixtures thereof. An adhesion force of the first adhesive layer 31 is greater than an adhesion force of the second adhesive layer 33. In at least one embodiment, this can be carried out by dissolving the rubber in methylbenzene to form a second adhesive. The second adhesive is coated on the surface 310 of the first adhesive layer 31 away from the release film 1, and is dried to form the second adhesive layer 33.

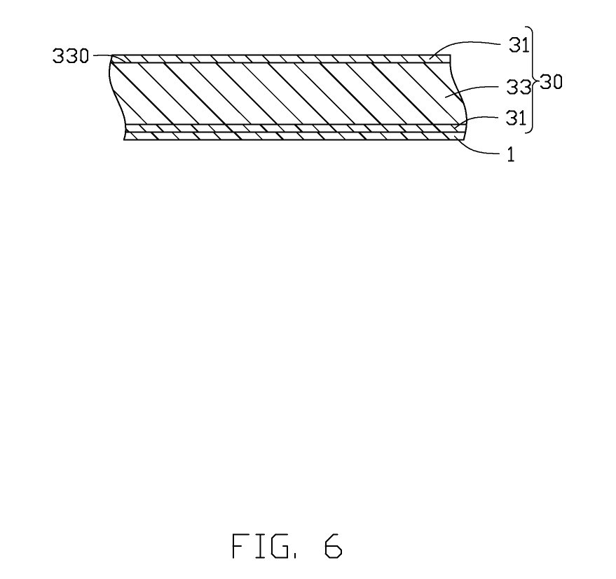

At block 303, FIG. 6 illustrates that another first adhesive layer 31 is connected to a surface 330 of the second adhesive layer 33 away from the release film 1, sandwiching the second adhesive layer 33 between the two first adhesive layers 31 to form the adhesive film 30. A ratio of a total thickness of the two first adhesive layers 31 with respect to a thickness of the adhesive film 30 is of about 0.1% to about 20%.

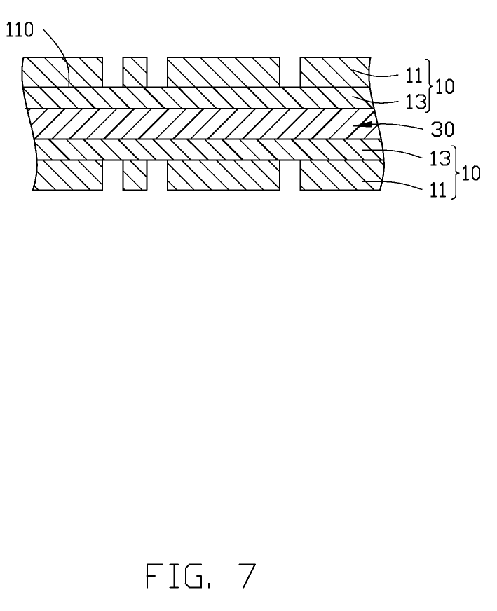

At block 304, FIG. 7 illustrates that at least two substrates 10 are provided. An adhesive film 30 is sandwiched between each two adjacent substrates 10, with each first adhesive layer 31 of each adhesive film 30 being connected to a substrate 10. In this embodiment, each substrate 10 comprises a base board 11 and a dielectric layer 13 connected to a surface 110 of the base board 11. The two first adhesive layers 31 of each adhesive film 30 are respectively connected to the two dielectric layers 13 of the two substrates 10 adjacent to the adhesive film 30. The dielectric layer 13 can be made of polyimide, liquid crystal polymer, or TEFLON.

At block 305, two protective films 60 (shown in FIG. 1) are respectively connected to the surfaces 111 of the two outermost substrates 10 away from the adhesive film 30. In at least one embodiment, each protective film 60 comprises an insulating layer 61 and a protective layer 63. The insulating layer 61 is connected to the surface 111 of the base board 11 of the outmost substrate 10 away from the adhesive film 30. The protective layer 63 is connected to the surface 611 of the insulating layer 61 away from the base board 11.

In another embodiment, the dielectric layer 13 of the base board 11 can be omitted. The two first adhesive layers 31 of the adhesive film 30 are respectively connected to the base boards 11 of the two substrates 10 adjacent to the adhesive film 30. In yet another embodiment, one first adhesive layer 31 of the adhesive film 30 is connected to the dielectric layer 13 of the substrate 10, and another first adhesive layer 31 of the adhesive film 30 is connected to the base board 11 of the substrate 10.

Having generally described this disclosure, a further understanding can be obtained by reference to certain specific examples which are provided herein for purposes of illustration only and are not intended to be limiting unless otherwise specified.

### EXAMPLE

A first adhesive was formed by dissolving the acrylonitrile-butadiene rubber and epoxy resin in butanone, and doping with N-isopropyl-N′-phenyl-4-phenylenediamin. The acrylonitrile-butadiene rubber and epoxy resin has a weight percentage of 25% of the total weight of the first adhesive. A second adhesive was formed by dissolving the rubber in methylbenzene. The styrene butadiene rubber had a weight percentage of 20% of a total weight of the second adhesive. Two first adhesive layers 31 were made by the first adhesive, and a second adhesive layer 33 was made by the second adhesive. The second adhesive layer 33 is sandwiched between the two first adhesive layers 31 to form an adhesive film 30. The adhesive film 30 had a thickness of about 25 μm. Each first adhesive layer 31 had a thickness of about 1 μm. Two substrates 10 were provided. Each substrate 10 comprises a base board 11 and a dielectric layer 13 made of liquid crystal polymer. The adhesive film 30 is sandwiched between the two substrates 10, with the two first adhesive layers 31 being respectively connected to the dielectric layers 13 of the two substrates 10. A surface 111 of each base board 11 away from the adhesive film 30 is connected to a protective film 60 to form a circuit board 100. Each protective film 60 comprises an insulating layer 61 and a protective layer 63. The insulating layer 61 is connected to the surface 111 of the base board 11. The protective layer 63 is connected to a surface 611 of the insulating layer 61 away from the base board 11.

### Comparison Example 1

An adhesive film was formed by an adhesive layer made of the first adhesive obtained from the example. The adhesive film has thickness of about 25 μm. Two substrates obtained from the example were provided. The adhesive film is sandwiched between the two substrates. A surface of each substrate away from the adhesive film is connected to a protective layer obtained from the example to form a circuit board.

### Comparison Example 2

An adhesive film was formed by an adhesive layer made of the second adhesive obtained from the example. The adhesive film has a thickness of about 25 μm. Two substrates obtained from the example were provided. The adhesive film is sandwiched between the two substrates. A surface of each substrate away from the adhesive film is connected to a protective layer obtained from the example to form a circuit board.

When a signal is transmitted through the adhesive film, the signal attenuation generated in the adhesive film during the signal transmission can be described as a function

α_{diel}: α_{diel}=(4.34/C)×W×D_{f}×√Dₖ=2.3×f×D_{f}×√Dₖ.

Wherein, f denotes a signal frequency of the adhesive film, D_{f} denotes a dielectric loss factor of the adhesive film, and Dₖ denotes a dielectric constant of the adhesive film . A peel strength between two adjacent substrates of each of the circuit boards obtained by the example and comparison examples 1 and 2, and a dielectric loss factor D_{f}, and a dielectric constant Dₖ of the adhesive film of each of the circuit boards obtained by the examples and comparison examples 1 and 2 under 10 GHz at a room temperature are measured. Table 1 illustrates the peel strength between two adjacent substrates of the circuit boards, and a dielectric loss factor D_{f} and a dielectric constant Dₖ of the adhesive film of the circuit boards.

TABLE 1

| | Peel strength | | |
|---|---|---|---|
| Circuit board | (kgf/cm) | D_{f} | Dₖ |
| Example | 0.7 | 2.6 | 0.005 |
| Comparison example 1 | 0.6 | 3.0 | 0.018 |
| Comparison example 2 | 0.2 | 2.5 | 0.004 |

Table 1 illustrates that since the adhesive film 30 of the example comprises two first adhesive layers 31 and a second adhesive layer 33, and the adhesive film of the comparison example 1 only comprises a first adhesive, the dielectric loss factor D_{f} and dielectric loss constant Dₖ of the adhesive film of the example are respectively less than the dielectric loss factor D_{f} and dielectric constant Dₖ of the comparison example 1. Thus, a signal attenuation generated in the adhesive film 30 of the example is less than a signal attenuation generated in the adhesive film of the comparative example No. 1.

Furthermore, since an adhesion force of the first adhesive layer 31 is greater than an adhesion force of the second adhesive layer 33, a peel strength between two adjacent substrates of the example is greater than a peel strength between two adjacent substrates of the comparison example 2, thereby causing structure of the circuit board to be firm.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A circuit board comprising:
at least two substrates each comprising a base board; and
an adhesive film sandwiched between and adhering two base boards, the adhesive film comprising two first adhesive layers and a second adhesive layer sandwiched between the two first adhesive layers;
wherein an adhesion force of each of the two first adhesive layers is greater than an adhesion force of the second adhesive layer, the second adhesive layer comprises rubber as a major composition, and the rubber is selected from a group consisting of isoprene rubber, styrene butadiene rubber, ethylene propylene rubber, butyl rubber, acrylic rubber, and polybutadiene rubber, and mixtures thereof.

2. The circuit board of the claim 1, wherein a ratio of a total thickness of the two first adhesive layers with respect to a thickness of the adhesive film is of 0.1% to 20%.

3. The circuit board of the claim 2, wherein the adhesive film has a thickness of 18 μm to 40 μm; and each first adhesive layer has a thickness of 0.1 μm to 3 μm.

4. The circuit board of the claim 1, wherein each of the at least two substrates further comprises a dielectric layer sandwiched between the base board and the corresponding first adhesive layer.

5. The circuit board of the claim 1, wherein each base board is a single-sided board or a double-sided board.

6. A method for making a circuit board comprising:
providing a release film comprising a surface;
forming a first adhesive layer on the surface of the release film;
forming a second adhesive layer on a surface of the first adhesive layer away from the release film, the second adhesive layer comprising rubber as a major composition, the rubber selected from a group consisting of isoprene rubber, styrene butadiene rubber, ethylene propylene rubber, butyl rubber, acrylic rubber, and polybutadiene rubber, and mixtures thereof, an adhesion force of the first adhesive layer being greater than an adhesion force of the second adhesive layer;
forming another first adhesive layer on a surface of the second adhesive layer away from the release film, to cause the second adhesive layer to be sandwiched between the two first adhesive layers to form an adhesive film;
providing at least two substrates each comprising a base board; and
connecting an adhesive film between each two adjacent substrates, to cause each first adhesive layers of each adhesive film being connected to a base board.

7. The method of the claim 6, wherein each first adhesive layer is formed by dissolving the acrylonitrile-butadiene rubber and epoxy resin in butanone, adding an additive to the butanone to form a first adhesive, coating the first adhesive on the surface of the release film or the surface of the second adhesive layer away from the release film, and drying the first adhesive, to form the first adhesive layer.

8. The method of the claim 6, wherein the second adhesive layer is formed by dissolving isoprene rubber, styrene butadiene rubber, ethylene propylene rubber, butyl rubber, acrylic rubber, or polybutadiene rubber, or mixtures thereof to form a second adhesive, coating the second adhesive on the surface of the first adhesive layer away from the release film to form the second adhesive layer.

9. The method of the claim 6, wherein the each substrate further comprises a dielectric layer; each first adhesive layers of each adhesive film is connected to the corresponding dielectric layer.

10. The method of the claim 6, wherein a ratio of a total thickness of the two first adhesive layers with respect to a thickness of the adhesive film is of 0.1% to 20%.
